(19) United States
(12) Patent Application Publication
(10) Pub. No.: US 2023/0182262 A1
(43) Pub. Date: Jun. 15, 2023

(54) SUBSTRATE CLEANING DEVICE AND SUBSTRATE POLISHING DEVICE

(71) Applicant: EBARA CORPORATION, Tokyo (JP)

(72) Inventors: ERINA BABA, Tokyo (JP); KOICHI FUKAYA, Tokyo (JP); KENICHI TAKEBUCHI, Tokyo (JP); KENICHIRO SAITO, Tokyo (JP)

(73) Assignee: EBARA CORPORATION, Tokyo (JP)

(21) Appl. No.: 18/075,439

(22) Filed: Dec. 6, 2022

(30) Foreign Application Priority Data
Dec. 10, 2021 (JP) 2021-200904

(51) Int. Cl. B24B 37/34; B24B 37/32; B08B 3/02; B08B 13/00

(52) U.S. Cl. CPC B24B 37/34; B24B 37/32; B08B 3/022; B08B 13/00

(57) ABSTRACT

A substrate cleaning device and a substrate polishing device are provided. The substrate cleaning device is provided in a substrate polishing device, which includes a polishing table having a polishing surface for polishing a substrate and a top ring holding the substrate with a membrane while surrounding an outer peripheral part of the substrate with a retainer ring, and cleaning the surface after polishing. The top ring is freely movable between a substrate polishing position above the table and a substrate handover position at a side of the table. The substrate cleaning device is provided corresponding to a cleaning position between the polishing and handover positions, and includes a first spray unit including cleaning nozzles for spraying cleaning liquid on the substrate, membrane, and retainer ring at the cleaning position; and a second spray unit including a substrate rinse nozzle spraying rinse liquid onto the substrate at the cleaning position.

### CROSS-REFERENCE TO RELATED APPLICATION

This application claims the priority benefits of Japanese application no. 2021-200904, filed on Dec. 10, 2021. The entity of the above-mentioned patent application is hereby incorporated by reference herein and made a part of this specification.

### BACKGROUND

### Technical Field

The disclosure relates to a device for cleaning substrates such as semiconductor wafers and a substrate polishing device including the cleaning device.

### Related Art

A polishing device for polishing the surface of a substrate such as a semiconductor wafer is provided with a polishing module, a cleaning module, and a substrate conveyance mechanism. The polishing module includes a polishing table having a polishing pad and a polishing head (top ring) for holding the substrate. The polishing head conveys the substrate between a handover position where a handover of the substrate is performed and a polishing position overlapping the polishing pad. At the polishing position, the substrate surface is pressed against the polishing pad with a predetermined pressure and the polishing pad and the substrate are moved relative to each other while a polishing liquid (slurry) is being supplied, such that the substrate is brought into sliding contact with the polishing pad and the surface of the substrate is polished flat.

The cleaning module includes multiple cleaning modules for performing rough cleaning (primary cleaning) and fine cleaning (secondary cleaning) of the substrate surface, and removes polishing residue (particles) such as polishing liquid and polishing waste remaining on the substrate after polishing treatment. The cleaning module includes a plurality of cleaning lines for cleaning a plurality of substrates, so as to achieve high throughput (see Patent Literature 1: JP-A-2010-50436).

Particles remaining on the substrate surface after polishing treatment affect the yield of semiconductor devices, so it is desired to completely remove particles in a cleaning part. However, particles on the surface of a substrate may dry out and adhere firmly while the substrate is conveyed from a polishing module to a cleaning module, which makes it difficult to completely remove the particles in the cleaning module. Therefore, it is desirable to clean the substrate immediately after polishing the substrate.

Moreover, as the substrate is polished, particles also adhere to the polishing head that holds the substrate and the retainer ring that laterally surrounds the substrate, it is desirable to perform the cleaning treatment on the polishing head and retainer ring prior to performing polishing treatment to the next substrate.

The disclosure provides a substrate cleaning device and a substrate polishing device that efficiently remove particles adhering to a substrate, a polishing head, and a retainer ring after polishing treatment.

### SUMMARY OF THE DISCLOSURE

One aspect of the disclosure is a substrate cleaning device provided in a substrate polishing device, which includes a polishing table having a polishing surface for performing a substrate polishing on a substrate and a top ring for holding the substrate with a membrane and pressing it against the polishing surface while surrounding an outer peripheral part of the substrate with a retainer ring, and cleaning a surface of the substrate after the substrate polishing. The top ring moves freely between a polishing position above the polishing table where the substrate polishing is performed and a handover position at a side of the polishing table where a handover of the substrate is performed. The substrate cleaning device is provided corresponding to a cleaning position between the polishing position and the handover position, and includes: a first spray unit for spraying a cleaning liquid toward the substrate, the membrane, and the retainer ring at the cleaning position; and a second spray unit for spraying a rinse liquid toward the substrate at the cleaning position.

One aspect of the disclosure is a substrate polishing device, including: a polishing table having a polishing surface for performing a substrate polishing on a substrate; a top ring moving freely between a polishing position above the polishing table where the substrate polishing is performed and a handover position at a side of the polishing table where a handover of the substrate is performed, and holding the substrate with a membrane and pressing it against the polishing surface while surrounding an outer peripheral part of the substrate with a retainer ring; a substrate cleaning part provided corresponding to a cleaning position between the polishing position and the handover position and cleaning a surface of the substrate after the substrate polishing; and a control part for controlling operations of the top ring and the substrate cleaning part. The substrate cleaning part includes: a first cleaning nozzle provided in plurality along a radial direction of the substrate held by the top ring at the cleaning position and having a plurality of spray ports for spraying a cleaning liquid toward the surface of the substrate; and a second cleaning nozzle having a plurality of spray ports for spraying the cleaning liquid toward the membrane and/or the retainer ring, and the control part controls to end spray from the first cleaning nozzle at the same time as or after the spray from the second cleaning nozzle ends.

One aspect of the disclosure is a substrate polishing device including a polishing table having a polishing surface for performing a substrate polishing on a substrate; a top ring moving freely between a polishing position above the polishing table where the substrate polishing is performed and a handover position at the side of the polishing table where a handover of the substrate is performed, and holding the substrate with a membrane and pressing it against the polishing surface while surrounding an outer peripheral part of the substrate with a retainer ring; a polishing surface cleaning part disposed above the polishing table cleaning the polishing surface after the substrate polishing; a substrate cleaning part provided corresponding to a cleaning position between the polishing position and the handover position and spraying a cleaning liquid toward the substrate, the membrane, and the retainer ring after the substrate polishing; and a control part for controlling operations of the top ring, the polishing surface cleaning part, and the substrate cleaning part. The control part controls to clean the substrate by the substrate cleaning part during a cleaning treatment of the polishing surface by the polishing surface cleaning part, and end the polishing surface cleaning treatment at the same time as or after the cleaning treatment of the substrate by the substrate cleaning part ends.

### BRIEF DESCRIPTION OF THE DRAWINGS

FIG. 1 is a plan view showing a schematic configuration of a substrate polishing device including a substrate cleaning device according to an embodiment of the disclosure.

FIG. 2 is a plan view showing a configuration of a polishing unit.

FIG. 3 is a perspective view showing the configuration of the polishing unit of FIG. 2.

FIG. 4 is a schematic cross-sectional view showing an internal configuration of the polishing unit of FIG. 2.

FIG. 5 is a plan view for illustrating how a substrate moves between a handover position, a cleaning position, and a polishing position.

FIG. 6 is a plan view showing a configuration of an auxiliary cleaning part.

FIG. 7 is a plan view showing a configuration of the auxiliary cleaning part, showing a state in which a cleaning liquid is sprayed.

FIG. 8 is a side view of an auxiliary cleaning part.

FIG. 9 is a functional block view showing a configuration of a substrate polishing device.

FIG. 10 is a flowchart of a substrate polishing and cleaning treatment.

### DESCRIPTION OF THE EMBODIMENTS

According to the disclosure, particles adhering to the substrate, polishing head, and retainer ring after polishing treatment can be efficiently removed.

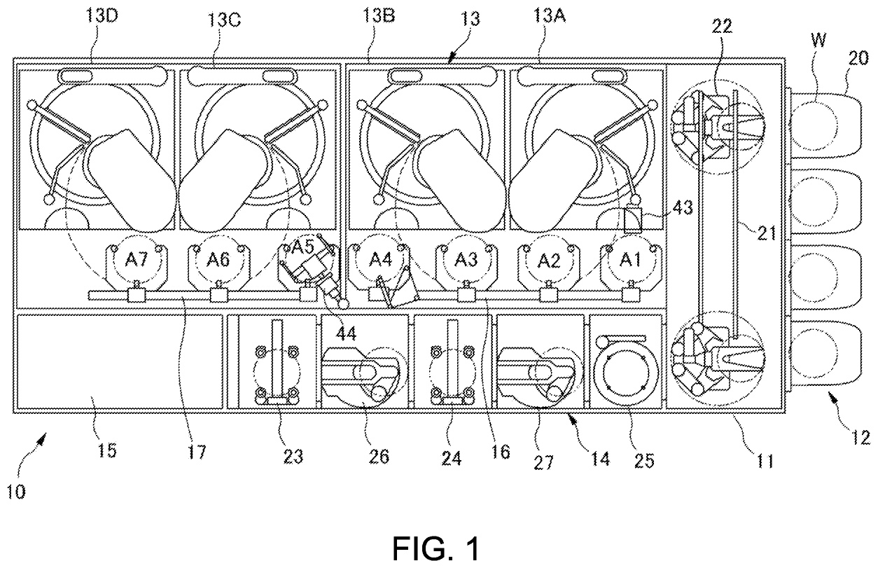

Hereinafter, embodiments of the disclosure will be described with reference to the drawings. FIG. 1 schematically shows a configuration of a substrate polishing device including a substrate cleaning device according to this embodiment. A substrate polishing device 10 includes a rectangular housing 11. The interior of the housing 11 is partitioned into a loading/unloading part 12, a polishing part 13, and a cleaning part 14 by partition walls. The substrate polishing device 10 also includes a control part 15 that controls the operation of each part.

The loading/unloading part 12 includes a plurality of front loading parts in which a plurality of substrate cassettes 20 accommodating substrates W such as semiconductor wafers are set. In the loading/unloading part 12, a traveling mechanism 21 is laid along a substrate cassette 20, and a conveying robot 22 movable along the arrangement direction in which the substrate cassette 20 is arranged is installed on the traveling mechanism 21. The conveying robot 22 receives a substrate W before polishing from the substrate cassette 20 and conveys it toward the polishing part 13, and receives the substrate W after polishing/cleaning treatment from the cleaning part 14.

The polishing part 13 includes a plurality of polishing units 13A-13D for polishing (flattening) the substrate W. The first polishing unit 13A to the fourth polishing unit 13D are arranged along the longitudinal direction of the substrate polishing device 10. Details of the configuration of the polishing unit will be described later.

A first linear transporter 16 is arranged adjacent to the first polishing unit 13A and the second polishing unit 13B. This first linear transporter 16 conveys the substrate W between four conveyance positions (a first conveyance position A1 to a fourth conveyance position A4 in order from the loading/unloading part 12 side) along the direction in which the polishing units 13A and 13B are arranged.

A second linear transporter 17 is arranged adjacent to the third polishing unit 13C and the fourth polishing unit 13D. This second linear transporter 17 conveys the substrate W between three conveyance positions (a fifth conveyance position A5 to a seventh conveyance position A7 in order from the loading/unloading part 12 side) along the direction in which the polishing units 13C and 13D are arranged.

The cleaning part 14 accommodates a first cleaning unit 23 and a second cleaning unit 24 for cleaning the substrate W after polishing, and a drying unit 25 for drying the substrate W after cleaning. Between the first cleaning unit 23 and the second cleaning unit 24, a first conveyance unit 26 for transferring the substrate W therebetween is arranged. Moreover, between the second cleaning unit 24 and the drying unit 25, a second conveyance unit for transferring the substrate W therebetween 27 is arranged.

In the first cleaning unit 23, a plurality of (for example, two) primary cleaning modules are vertically arranged. Similarly, in the second cleaning unit 24, a plurality of (for example, two) secondary cleaning modules are vertically arranged. The primary cleaning module and the secondary cleaning module are cleaning machines that clean the substrate using a cleaning liquid, and footprint may be reduced by vertical arrangement.

A roll sponge type cleaning machine may be used as the primary cleaning module and the secondary cleaning module. The primary cleaning module and secondary cleaning module may be the same type of cleaning module or different types of cleaning modules. For example, the primary cleaning module may be a cleaning machine of a type in which the upper and lower surfaces of the substrate are scrubbed with a pair of roll sponges, and the secondary cleaning module may be a pencil sponge cleaning machine or a two-fluid jet cleaning machine. The two-fluid jet cleaning machine is a cleaning machine that mixes pure water (DIW) in which a small amount of N₂ gas (carbon dioxide gas) is dissolved and N₂ gas, and blows the mixed fluid onto the surface of the substrate, and is capable of removing tiny particles on the substrate by minute droplets and impact energy.

In the drying unit 25, a plurality of (for example, two) drying modules are vertically arranged to dry the substrate W by spraying gas from a nozzle (not shown) toward the rotating substrate W. Alternatively, the substrate W may be dried by centrifugal force by rotating the substrate W at high speed. The conveying robot 22 takes out the substrate W after cleaning/drying treatment from the drying unit 25 and returns it to the substrate cassette 20.

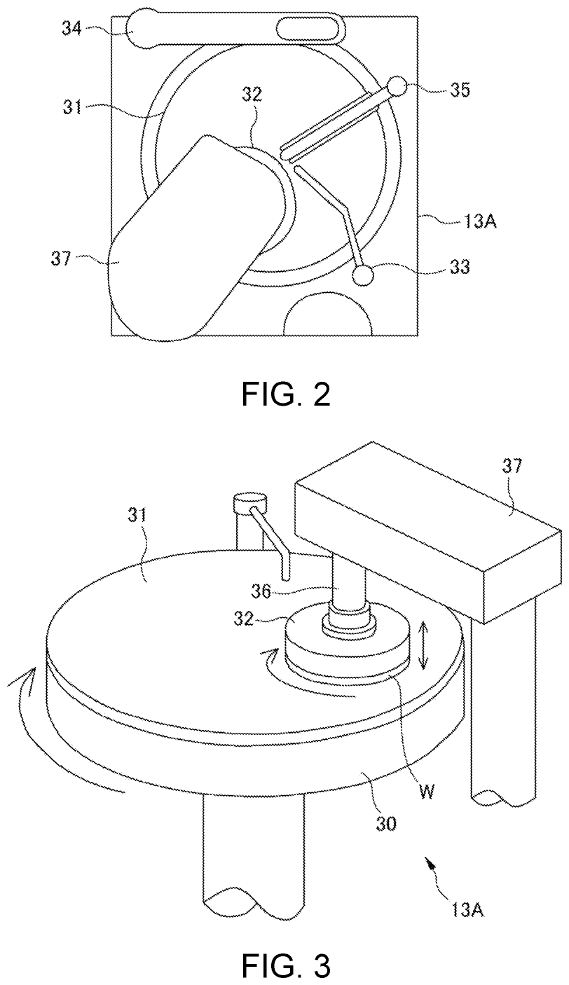

FIGS. 2 and 3 show a schematic configuration of the first polishing unit 13A according to this embodiment. The second polishing unit 13B to the fourth polishing unit 13D have the same configuration as the first polishing unit 13A, therefore the first polishing unit 13A will be described below.

The first polishing unit 13A includes a polishing table 30 to which a polishing pad 31 having a polishing surface is mounted; a top ring 32 for polishing while holding the substrate W and pressing it against the polishing pad 31 on the polishing table 30 with a predetermined pressure; a polishing liquid supply nozzle 33 for supplying polishing liquid or dressing liquid (for example, pure water) to the polishing pad 31; a dresser 34 for dressing the polishing surface of the polishing pad 31; and an atomizer 35 for atomizing a mixed fluid of liquid (for example, pure water) and gas (for example, nitrogen gas) or liquid (for example, pure water) and spraying it onto the polishing surface. The top ring 32 is rotatable by a swing arm 37 connected via a top ring shaft 36.

The polishing pad 31 attached on the polishing table 30 constitutes a polishing surface for polishing the substrate W. Moreover, fixed abrasive grains may be used instead of the polishing pad 31. The top ring 32 and the polishing table 30 are configured to rotate about their axes, as indicated by arrows in FIG. 3. The substrate W is held by vacuum suction on a lower surface of the top ring 32. A polishing liquid is supplied from the polishing liquid supply nozzle 33 to an upper surface (polishing surface) of the polishing pad 31, and the substrate W is pressed against the polishing pad 31 by the top ring 32 and polished.

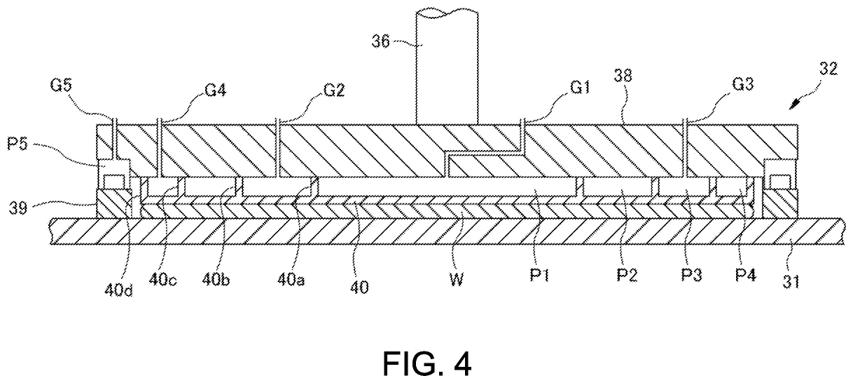

In FIG. 4, the top ring 32 is connected to a lower end of the top ring shaft 36 via a universal joint (not shown) which is a ball joint. The top ring 32 includes a substantially disk-shaped top ring body 38, a retainer ring 39 disposed below the top ring body 38, and a circular membrane (elastic pad) 40 abutting on the substrate W. The top ring body 38 is made of a material having high strength and rigidity, such as metal or ceramics. Further, the retainer ring 39 is made of a highly rigid resin material, ceramics, or the like.

A membrane 40 is mounted on a lower surface of the top ring body 38. Between the membrane 40 and the top ring body 38, a plurality of pressure chambers (airbags) P1, P2, P3, P4 are formed by a plurality of partition walls 40a-40d formed on the membrane 40. The pressure chambers P1, P2, P3, and P4 are supplied with pressurized fluid, such as pressurized air, through the fluid passages G1, G2, G3, and G4, respectively, or are or evacuated. The central pressure chamber P1 is circular, the other pressure chambers P2, P3, P4 are annular, and these pressure chambers P1, P2, P3, and P4 are arranged concentrically.

The internal pressures of the pressure chambers P1, P2, P3, and P4 may be changed independently of each other by a pressure adjustment part (not shown). As a result, the pressing forces on four regions of the substrate W, namely a central part, an inner middle part, an outer middle part, and a peripheral edge part, may be adjusted independently.

In order to prevent the substrate W being polished from flying out of the top ring 32, the retainer ring 39 is provided on the lower surface of the top ring 32 for holding by surrounding the outer peripheral part of the substrate W. An opening is formed in the portion of the membrane 40 that constitutes the pressure chamber P3, and the substrate W is held by the top ring 32 by suction by forming a vacuum in the pressure chamber P3. Further, the substrate W is released from the top ring 32 by supplying nitrogen gas, dry air, compressed air, or the like to the pressure chamber P3.

An elastic bag forming a pressure chamber P5 is arranged between the retainer ring 39 and the top ring body 38. The retainer ring 39 may move up and down relative to the top ring body 38. A fluid passage G5 communicates with the pressure chamber P5, and a pressurized fluid such as pressurized air is supplied to the pressure chamber P5 through the fluid passage G5. The internal pressure of the pressure chamber P5 may be adjusted by a pressure adjustment part, and the pressing force of the retainer ring 39 against the polishing pad 31 may be adjusted independently of the pressing force against the substrate W.

The substrate may be polished in any one of the first polishing unit 13A, the second polishing unit 13B, the third polishing unit 13C and the fourth polishing unit 13D, or may be continuously polished by a plurality of polishing units preselected from these polishing units 13A-13D. By leveling the polishing times of all the polishing units 13A-13D, throughput can be improved.

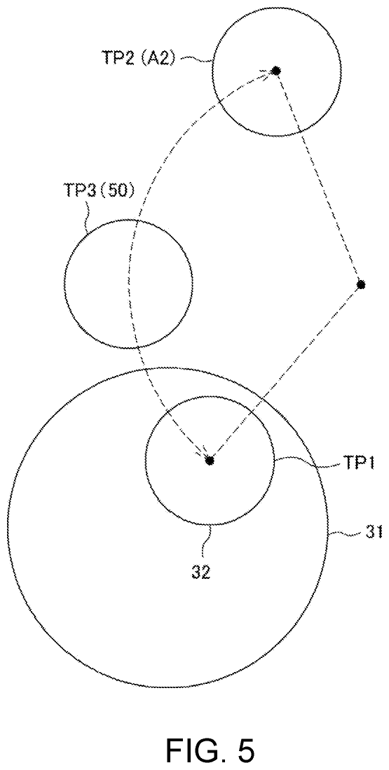

In FIG. 1, the substrate W is conveyed by the first linear transporter 16 to the polishing units 13A and 13B. The top ring 32 of the first polishing unit 13A moves between a polishing position TP1 above the polishing table 30 (reference numeral omitted in FIG. 5, the polishing pad 31) and the second conveyance position A2 on the side of the polishing table 30. The handover of the substrate to the top ring 32 is performed at the second conveyance position A2, and this second conveyance position A2 becomes a handover position TP2 (see FIG. 5).

Similarly, the top ring of the second polishing unit 13B (the third polishing unit 13C, the fourth polishing unit 13D) moves between the polishing position above the polishing table (polishing pad) and the third conveyance position A3 (the sixth conveyance position A6 for the third polishing unit 13C and the seventh conveyance position A7 for the fourth polishing unit 13D) on the side of the polishing table, and the handover of the substrate to the top ring is performed at the third conveyance position A3 (the sixth conveyance position A6 and the seventh conveyance position A7) as the handover position of the substrate.

A lifter 43 for receiving the substrate from the conveying robot 22 is arranged at the first conveyance position A1. The substrate is transferred from the conveying robot 22 to the first linear transporter 16 via this lifter 43. Moreover, between the first linear transporter 16, the second linear transporter 17 and the cleaning part 14, a swing transporter 44 having a reversing function is arranged to hand over the substrate from the first linear transporter 16 to the second linear transporter 17 and convey the substrate from the polishing part 13 to the cleaning part 14.

As described, the top ring 32 of the first polishing unit 13A is configured to move between the polishing position TP1 above the polishing table 30 (reference numeral omitted in FIG. 5, the polishing pad 31) and the handover position TP2 (A2 in FIG. 1) of the substrate on the side of the polishing table 30. The top ring 32 of the first polishing unit 13A is further configured to stop at a cleaning position TP3 between the polishing position TP1 and handover position TP2 (the second conveyance position A2) of the substrate, and an auxiliary cleaning part 50 is arranged at a position of the top ring 32 corresponding to the cleaning position TP3.

FIG. 5 shows an outline of the positional relationship between the polishing table 30 (reference numeral omitted in FIG. 5, the polishing pad 31), the top ring 32, and the auxiliary cleaning part 50 of the first polishing unit 13A. The top ring 32 is rotatable by the swing arm 37 connected via the top ring shaft 36, and is configured to move between the polishing position TP1 above the polishing table 31, the handover position TP2 (the second conveyance position A2) lateral to the polishing table 30, and the cleaning position TP3 between the polishing position TP1 and the handover position TP2. The auxiliary cleaning part 50 is arranged at a position of the top ring 32 corresponding to the cleaning position TP3. The configurations of the top ring 32 and the auxiliary cleaning part 50 are the same for the second polishing unit 13B to the fourth polishing unit 13D, and detailed description thereof will be omitted.

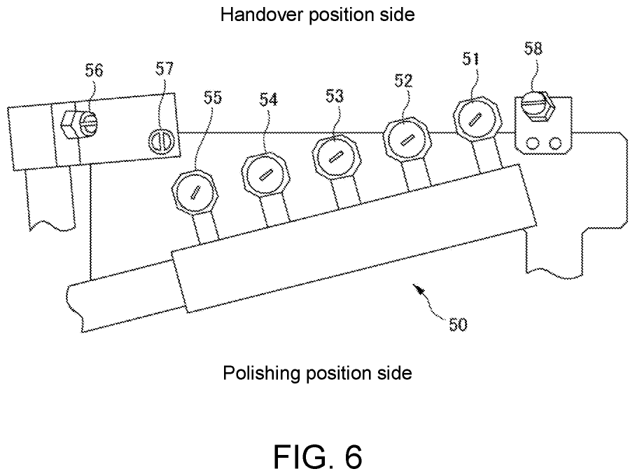

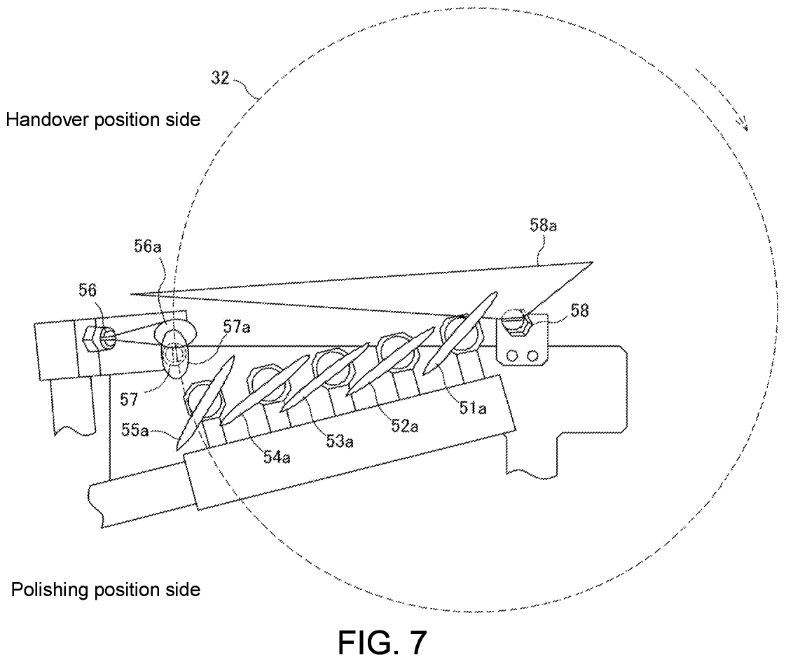

FIGS. 6 and 7 are plan views showing the configuration of the auxiliary cleaning part 50. The auxiliary cleaning part 50 includes a plurality (five in this embodiment) of substrate cleaning nozzles 51-55, a retainer ring (RR) side cleaning nozzle 56, an RR/membrane inter-cleaning nozzle 57, and a substrate rinse nozzle 58, and performs cleaning treatment on the top ring 32 holding the polished substrate W at the cleaning position TP3. As a result, cleaning treatment may be performed on the substrate W after polishing treatment before it is conveyed to the cleaning part 14, and particles remaining on the substrate surface can be effectively removed.

The substrate cleaning nozzles 51-55 are arranged linearly along the radial direction of the top ring 32 below the top ring 32 when the top ring 32 is positioned at the cleaning position TP3. At the cleaning position TP3, the substrate cleaning nozzles 51-55 spray the cleaning liquid obliquely upward to the surface of the substrate W rotating together with the top ring 32 in the direction of the arrow shown in FIG. 7. In the example of FIG. 7, the first substrate cleaning nozzle 51 is arranged the vicinity of the center of the top ring 32, and the fifth substrate cleaning nozzle 55 is arranged near the outer peripheral part of the top ring 32. As shown in FIG. 7, the shape of the cleaning liquid sprayed from each of the substrate cleaning nozzles 51-55 is formed into elongated and substantially elliptical shapes 51a-55a, respectively, and the long axis thereof is in a direction slightly inclined from the radial direction of the top ring 32. As a result, when the top ring 32 rotates, the cleaning liquid is easily diffused over the entire surface of the substrate W.

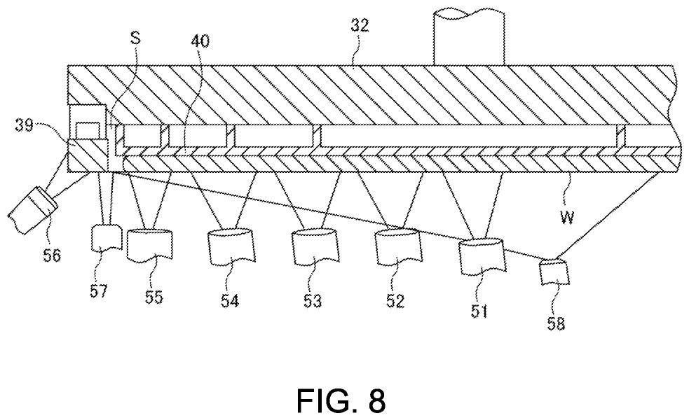

FIG. 8 is a side view of the auxiliary cleaning part 50. The substrate cleaning nozzles 51-55 are arranged to be inclined in the outer peripheral direction of the top ring 32 at the cleaning position TP3. As a result, as the top ring 32 rotates, the cleaning liquid sprayed from the substrate cleaning nozzles 51-55 is easily diffused toward the outer peripheral part of the top ring 32, and the particles adhering to the substrate W and the top ring 32 are easily discharged to the outside.

The retainer ring (RR) side cleaning nozzle 56 is arranged below the top ring 32 positioned at the cleaning position TP3, and sprays a cleaning liquid 56a obliquely upward toward side and bottom surfaces of the retainer ring 39 while the top ring 32 is rotating at the cleaning position TP3. As a result, particles adhering to the side surface of the retainer ring 39 after polishing treatment can be removed.

Further, the RR/membrane inter-cleaning nozzle 57 is arranged below the top ring 32 positioned at the cleaning position TP3, and sprays a cleaning liquid 57a vertically upward toward a boundary between the retainer ring 39 and the membrane 40 while the top ring 32 is rotating at the cleaning position TP3. As a result, particles adhering to a gap S (see FIG. 8) between the retainer ring 39 and the membrane 40 after polishing treatment can be removed.

By spraying the cleaning liquid from the retainer ring (RR) side cleaning nozzle 56 and the RR/membrane inter-cleaning nozzle 57, particles adhering to the retainer ring 39 and the membrane 40 may be scattered toward the substrate W held by the top ring 32. For this reason, the timing of stopping the spray of the cleaning liquid from the retainer ring (RR) side cleaning nozzle 56 and the RR/membrane inter-cleaning nozzle 57 is controlled so as to be simultaneous with or earlier than the timing of stopping the spray of the cleaning liquid from the substrate cleaning nozzles 51-55.

When the spraying of the retainer ring (RR) side cleaning nozzle 56 and the RR/membrane inter-cleaning nozzle 57 is stopped after the substrate cleaning nozzles 51-55, particles may be scattered on the substrate W. However, by stopping the spray from these nozzles 51-57 at the same time, it is possible to reduce the possibility that particles adhering to the retainer ring 39 and the membrane 40 are scattered toward the substrate W held by the top ring 32. Moreover, by making the timing of stopping the spray from the retainer ring (RR) side cleaning nozzle 56 and the RR/membrane inter-cleaning nozzle 57 earlier than the timing of stopping the spray of the cleaning liquid from the substrate cleaning nozzles 51-55, even if particles are scattered on the substrate W, they may be removed by spraying the cleaning liquid from the substrate cleaning nozzles 51-55.

As the cleaning liquid sprayed from the substrate cleaning nozzles 51-55, the retainer ring (RR) side cleaning nozzle 56, and the RR/membrane inter-cleaning nozzle 57, for example, pure water, acidic or alkaline chemicals or surfactants, one to which ultrasonic waves are applied, high-speed liquid droplets or mist generated by pressurized spraying of a mixed fluid (two fluids) containing a trace amount of carbon dioxide (pure water and the like) and gas, and high-speed sprayed liquid may be used.

The substrate rinse nozzle 58 is arranged below the vicinity of the center of the top ring 32 positioned at the cleaning position TP3, and sprays a rinse liquid 58a (for example, pure water) obliquely upward while the top ring 32 is rotating at the cleaning position TP3. The substrate rinse nozzle 58 sprays the rinse liquid, preferable to the downstream side of the spraying position of the cleaning liquid by the substrate cleaning nozzles 51-55 with respect to the rotation direction of the top ring 32.

The timing of stopping the spray of the rinse liquid from the substrate rinse nozzle 58 is preferably the timing after the spray of the cleaning liquid from the substrate cleaning nozzles 51-55, the retainer ring (RR) side cleaning nozzle 56, and the RR/membrane inter-cleaning nozzle 57 is stopped. As a result, the cleaning liquid adhering to the substrate W may be cleaned away by the substrate cleaning nozzles 51-55, the retainer ring (RR) side cleaning nozzle 56, and the RR/membrane inter-cleaning nozzle 57.

When performing the cleaning treatment at the cleaning position TP3, by increasing the rotation speed of the top ring 32, the number of times the substrate W passes through the auxiliary cleaning part 50 increases, so cleaning performance after the substrate polishing treatment can be improved. Further, by increasing the rotation speed of the top ring 32, the particles adhering to the substrate W may be easily discharged to the outside by the centrifugal force, so cleaning performance can be improved. On the other hand, by increasing the rotation speed of the top ring 32, the substrate W becomes easier to dry, and as a result, particles may adhere to the substrate W firmly. By spraying the rinse liquid onto the substrate W from the substrate rinse nozzle 58, even if the rotational speed of the top ring 32 is increased to improve cleaning performance, the substrate W may be prevented from drying out.

The spray shape of the rinse liquid from the substrate rinse nozzle 58 is preferably a line-shaped spray including the vicinity of the center of the top ring 32, as shown in FIG. 7. As a result, rotation of the top ring 32 allows the rinse liquid to adhere over a wide range including the central part of the substrate W supported by the top ring 32, thereby effectively preventing the substrate W from drying. Further, as shown in FIG. 8, the substrate rinse nozzle 58 is arranged at an angle with respect to the top ring 32 at the cleaning position TP3. As a result, as the top ring 32 rotates, the rinse liquid sprayed from the substrate rinse nozzle 58 easily moves toward the outer peripheral part of the top ring 32.

Inside the housing 11, the control part 15 for controlling the operation of each part of the substrate polishing device 10 is arranged. The control part 15 is, for example, a general-purpose computer device, and includes a CPU, a storage part (memory) 60 for storing control programs, a display part, and the like. The control part 15 also includes an input part that receives an external input. Here, the external input may include mechanical operation by users and signal input from external devices, wire or wireless.

The control part 15 controls the movement of each machine of the substrate polishing device 10 by activating the control program stored in the storage part (memory) 60. The control program for controlling the operation of the substrate polishing device 10 may be installed in advance in a computer that constitutes the control part 15, stored in a storage medium such as a DVD, BD, SSD, or the like, or installed in the control part 15 via the Internet.

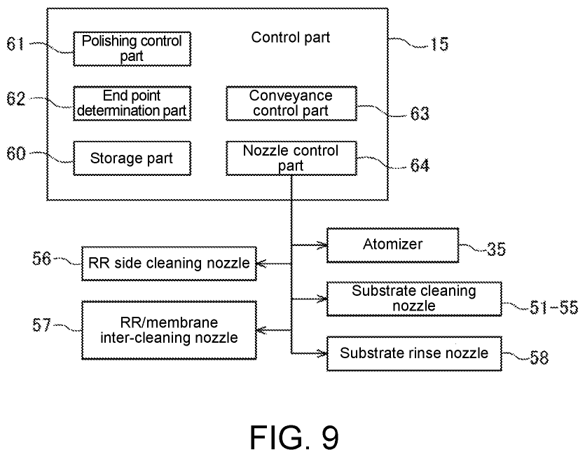

FIG. 9 is an example showing a functional block view of the control part 15 of the substrate polishing device 10. The control part 15 includes the storage part 60, a polishing control part 61, an end point determination part 62, a conveyance control part 63 and a nozzle control part 64. The polishing control part 61 controls the rotation of the polishing table 30 and the top ring 32, and controls the pressures of the pressure chambers P1-P5. The end point determination part 62 determines whether or not a polishing amount of the substrate W has reached a set value using an optical sensor (not shown) or the like, and ends the substrate polishing when it has reached the set value. The conveyance control part 63 controls conveyance of the substrate W within the substrate polishing device 10, including conveyance of the substrate W in the polishing units 13A-13D.

The nozzle control part 64 is connected to the atomizer 35, the substrate cleaning nozzles 51-55, the RR side cleaning nozzle 56, the RR/membrane inter-cleaning nozzle 57, and the substrate rinse nozzle 58, and controls spray of cleaning liquid, rinse liquid, and the like.

Here, when the cleaning liquid or the like is sprayed from various nozzles constituting the auxiliary cleaning part 50 while rotating the top ring 32 at the cleaning position, droplets containing particles adhering to the substrate W, the top ring 32, and the retainer ring 39 are scattered from the outer peripheral part of the top ring 32. When droplets scattered from the top ring 32 reach the polishing table 30, the polishing pad 31 is contaminated, and thus, scratches may occur when the next substrate W is polished.

Therefore, the positions of the various nozzles and the rotating direction of the top ring are set such that the cleaning liquid and the like from the various nozzles constituting the auxiliary cleaning part 50 flow in the direction of the handover position TP2. In the example of FIG. 7, when the auxiliary cleaning part 50 is arranged on the left side of the center of the top ring 32, the top ring 32 is controlled to rotate clockwise. On the other hand, when the auxiliary cleaning part 50 is arranged on the right side of the center of the top ring 32, the top ring 32 is controlled to rotate counterclockwise. As a result, as the top ring 32 rotates, the cleaning liquid and the rinse liquid from various nozzles constituting the auxiliary cleaning part 50 flow toward the handover position, therefore droplets scattered from the top ring 32 can be prevented from reaching the polishing table 31.

Moreover, after performing polishing treatment to the substrate W, while the cleaning liquid is sprayed from the atomizer 35 onto the polishing pad 31 continuing rotation integrally with the polishing table 30, dressing and cleaning treatments on the polishing pad 31 are performed by the dresser 34 which is brought into contact with the polishing pad 31 by an elevation/swing mechanism (not shown) and is swung in the substantially radial direction. The control part 15 controls the end timing of the spray of the cleaning liquid from the atomizer 35 (end timing of cleaning the polishing pad 31) so as to be simultaneous with or after the end timing of the spray of the cleaning liquid or the like from the various nozzles constituting the auxiliary cleaning part 50.

In a case where spray of the cleaning liquid or the like from the nozzle of the auxiliary cleaning part 50 is ended after the spray of the cleaning liquid from the atomizer 35 ends, droplets may be scattered from the top ring 32 onto the polishing table 30. However, by simultaneously stopping the spray from the atomizer 35 and the auxiliary cleaning part 50, the possibility of particles scattering onto the polishing table 30 can be reduced. Moreover, by ending the spraying of the cleaning liquid from the atomizer 35 after the spraying of the cleaning liquid from the nozzles of the auxiliary cleaning part 50 ends, even if droplets are scattered from the top ring 32 onto the polishing table 30 due to the cleaning treatment by the auxiliary cleaning part 50, they can be removed by spraying the cleaning liquid from the atomizer 35.

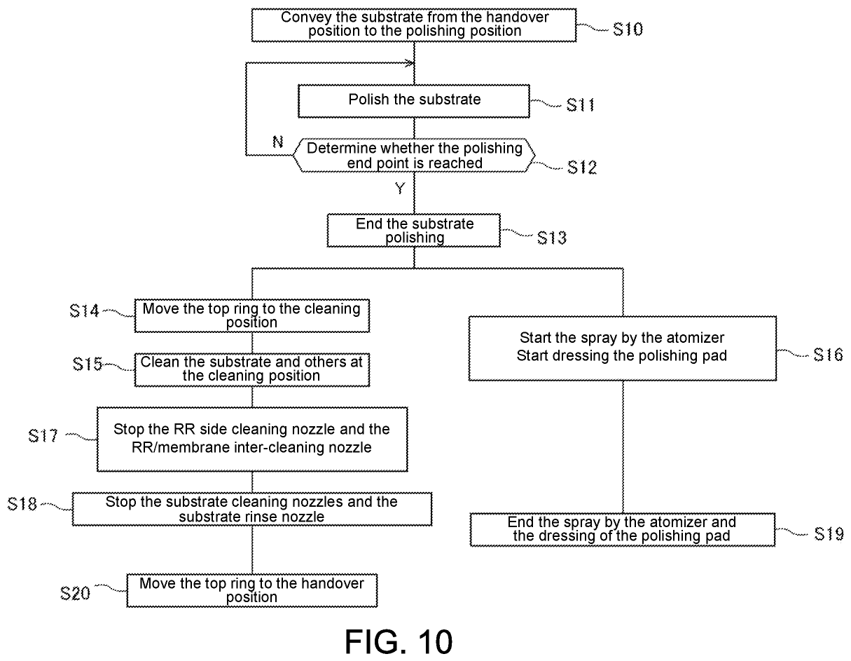

Substrate polishing and post-polishing cleaning treatment in the substrate polishing device 10 will be described below with reference to the flow chart of FIG. 10. When the substrate W is conveyed to the polishing unit 13A, the top ring 32 holds the substrate W in a position surrounded by the retainer ring 39 by vacuum suction, and conveys it from the handover position TP2 to the polishing position TP1 (step S10). The polishing unit 13A performs polishing treatment on the substrate W by pressing the substrate W, which has reached the polishing position TP1, against the polishing pad 31 (step S11). The film thickness of the substrate W is measured during substrate polishing, and it is determined whether or not a predetermined film thickness is reached (whether or not the polishing end point is reached) (step S12), and when the polishing end point is reached, the substrate polishing is ended (step S13).

Then, the top ring 32 is moved to the cleaning position TP3 (step S14). When the top ring 32 reaches the cleaning position TP3, while the top ring 32 is rotated, various nozzles constituting the auxiliary cleaning part 50 are driven to perform cleaning treatment on the substrate W, the top ring 32 and the retainer ring 39 (step S15). As a result, particles adhering to the substrate W, the top ring 32 and the retainer ring 39 due to substrate polishing are discharged to the outside of the top ring 32.

Further, the auxiliary cleaning part 50 drives the substrate rinse nozzle 58 to spray the rinse liquid toward the substrate W. As a result, drying of the substrate W caused by rotating the top ring 32 during post-polishing cleaning can be prevented.

After step S14, the atomizer 35 is driven to spray the cleaning liquid onto the polishing pad 31, and the dresser 34 is driven to dress the polishing pad 31 (step S16). As a result, the cleaning treatment for the substrate W held by the top ring 32 and the dressing treatment for the polishing pad 31 are performed in parallel. The dressing treatment and cleaning treatment of the polishing pad 31 are performed in parallel with the post-polishing cleaning treatment of the top ring 32 and the substrate W by the auxiliary cleaning part 50.

After a certain period of time has passed, the RR side cleaning nozzle 56 and the RR/membrane inter-cleaning nozzle 57 are stopped, and the cleaning treatment for the retainer ring 39 and the membrane 40 is ended (step S17). Then, the substrate cleaning nozzles 51-55 and the substrate rinse nozzle 58 are stopped (step S18). As a result, the post-polishing cleaning treatment for the substrate W is ended.

Then, the spray of the cleaning liquid by the atomizer 35 and the dressing treatment of the polishing pad 31 are ended (step S19). As a result, the possibility that droplets containing particles from the top ring 32 remain on the polishing pad 31 due to the post-polishing cleaning treatment can be eliminated. The top ring 32 is then moved to the handover position TP2 (step S20), and the substrate W after polishing is conveyed to the cleaning part 14.

Moreover, at the standby time for treatment when the substrate W is not positioned at the cleaning position (a state in which the post-polishing cleaning treatment is not performed on the substrate W), it is desirable to intermittently spray a small amount of ultrapure water from each nozzle constituting the auxiliary cleaning part 50 to suppress the generation of bacteria and the like.

The above-described embodiments are described for the purpose of enabling a person having ordinary knowledge in the technical field to which the disclosure belongs to implement the disclosure. A variety of modifications of the above embodiments may be made by those skilled in the art, and the technical idea of the disclosure may be applied to other embodiments. The disclosure is not limited to the described embodiments, but is to be construed in its broadest scope according to the technical concept defined by the claims.

What is claimed is:

1. A substrate cleaning device provided in a substrate polishing device, which comprises a polishing table having a polishing surface for performing a substrate polishing on a substrate and a top ring for holding the substrate with a membrane and pressing it against the polishing surface while surrounding an outer peripheral part of the substrate with a retainer ring, and cleaning a surface of the substrate after the substrate polishing,
wherein the top ring moves freely between a polishing position above the polishing table where the substrate polishing is performed and a handover position at a side of the polishing table where a handover of the substrate is performed, and
the substrate cleaning device is provided corresponding to a cleaning position between the polishing position and the handover position, and comprises:
a first spray unit for spraying a cleaning liquid toward the substrate, the membrane, and the retainer ring at the cleaning position; and
a second spray unit for spraying a rinse liquid toward the substrate at the cleaning position.

2. The substrate cleaning device according to claim 1,
wherein the first spray unit comprises:
a first cleaning nozzle provided in plurality along a radial direction of the substrate at the cleaning position and comprising a plurality of spray ports for spraying the cleaning liquid toward the surface of the substrate; and
a second cleaning nozzle comprising a spray port for spraying the cleaning liquid toward the membrane and/or the retainer ring.

3. The substrate cleaning device according to claim 2, wherein the second cleaning nozzle comprises a spray port for spraying the cleaning liquid toward a gap between the membrane and the retainer ring.

4. The substrate cleaning device according to claim 1, wherein the second spray unit is arranged downstream of the first spray unit in a rotational direction of the top ring.

5. The substrate cleaning device according to claim 2, wherein the second spray unit is arranged downstream of the first spray unit in a rotational direction of the top ring.

6. The substrate cleaning device according to claim 3, wherein the second spray unit is arranged downstream of the first spray unit in a rotational direction of the top ring.

7. The substrate cleaning device according to claim 1, wherein a spray nozzle of the first spray unit is inclined toward the handover position.

8. The substrate cleaning device according to claim 2, wherein a spray nozzle of the first spray unit is inclined toward the handover position.

9. The substrate cleaning device according to claim 3, wherein a spray nozzle of the first spray unit is inclined toward the handover position.

10. A substrate polishing device, comprising the substrate cleaning device and the top ring according to claim 1 and a polishing pad.

11. A substrate polishing device, comprising the substrate cleaning device and the top ring according to claim 2 and a polishing pad.

12. A substrate polishing device, comprising the substrate cleaning device and the top ring according to claim 3 and a polishing pad.

13. A substrate polishing device, comprising:
a polishing table having a polishing surface for performing a substrate polishing on a substrate;
a top ring moving freely between a polishing position above the polishing table where the substrate polishing is performed and a handover position at a side of the polishing table where a handover of the substrate is performed, and holding the substrate with a membrane and pressing it against the polishing surface while surrounding an outer peripheral part of the substrate with a retainer ring;
a substrate cleaning part provided corresponding to a cleaning position between the polishing position and the handover position and cleaning a surface of the substrate after the substrate polishing; and
a control part for controlling operations of the top ring and the substrate cleaning part;
wherein the substrate cleaning part comprises:
a first cleaning nozzle provided in plurality along a radial direction of the substrate held by the top ring at the cleaning position and having a plurality of spray ports for spraying a cleaning liquid toward the surface of the substrate; and
a second cleaning nozzle having a plurality of spray ports for spraying the cleaning liquid toward the membrane and/or the retainer ring,
wherein the control part controls to end spray from the first cleaning nozzle at the same time as or after the spray from the second cleaning nozzle ends.

14. A substrate polishing device, comprising:
a polishing table having a polishing surface for performing a substrate polishing on a substrate;
a top ring moving freely between a polishing position above the polishing table where the substrate polishing is performed and a handover position at a side of the polishing table where a handover of the substrate is performed, and holding the substrate and pressing it against the polishing surface with a membrane while surrounding an outer peripheral part of the substrate with a retainer ring;
a polishing surface cleaning part disposed above the polishing table and cleaning the polishing surface after the substrate polishing;
a substrate cleaning part provided corresponding to a cleaning position between the polishing position and the handover position and spraying a cleaning liquid toward the substrate, the membrane, and the retainer ring after the substrate polishing; and
a control part for controlling operations of the top ring, the polishing surface cleaning part, and the substrate cleaning part,
wherein the control part controls to clean the substrate by the substrate cleaning part during a cleaning treatment of the polishing surface by the polishing surface cleaning part, and end the cleaning treatment of the polishing surface at the same time as or after the cleaning treatment of the substrate by the substrate cleaning part ends.
